(19) United States
(12) Patent Application Publication
(10) Pub. No.: US 2011/0272014 A1
(43) Pub. Date: Nov. 10, 2011

(54) Photovoltaic Structure And Method Of Fabication Employing Nanowire In Stub

(76) Inventors: Sagi V. Mathai, Palo Alto, CA (US); Nobuhiko P. Kobayashi, Palo Alto, CA (US); Shih-Yuan Wang, Palo Alto, CA (US)

(21) Appl. No.: 13/133,513

(22) PCT Filed: Dec. 19, 2008
(86) PCT No.: PCT/US08/87848

§ 371 Date: Jul. 27, 2011

(51) Int. Cl. H01L 31/06; H01L 31/18; B82Y 99/00

(52) U.S. Cl. 136/255; 438/97; 977/762; 977/948; 257/E31.038

(57) ABSTRACT

A photovoltaic structure of a photovoltaic cell and a method of fabricating a photovoltaic structure, employ a nanowire having a base connected to a stub and an electrical isolation layer surrounding the stub. The stub is a constituent of a substrate surface. The nanowire extends away from the substrate surface and is wider than the stub. The nanowire base overlies a part of the isolation layer that is adjacent to the stub. A semiconductor junction comprises the nanowire. The method includes forming the stub; growing the nanowire from the stub; and conformally coating the nanowire. A nanoparticle is applied to the substrate surface. The isolation layer is created on and embedded in the substrate surface using the nanoparticle as a mask. A portion of the substrate surface underlying the nanoparticle forms the stub. The nanoparticle catalyzes nanowire growth on the stub. The stub is narrower than the nanoparticle.

### CROSS-REFERENCE TO RELATED APPLICATIONS

NA

### STATEMENT REGARDING FEDERALLY SPONSORED RESEARCH OR DEVELOPMENT

N/A

### BACKGROUND

1. Technical Field

The invention relates to photovoltaic devices. In particular, the invention relates to a nanowire-based photovoltaic structure for a photovoltaic cell and method of making same using a nanowire grown from a stub on a substrate surface.

2. Description of Related Art

Photonic devices, such as photovoltaic cells, are the subject of much interest due to high energy costs and U.S. dependence on fossil fuel from foreign sources. The efficiency and quality of photovoltaic cells have improved significantly over the last 10 years. Efforts to lower the cost of photovoltaic cells have been directed at alternative materials and manufacturing methods.

Historically, high performance semiconductor devices, especially those with p-n junctions, comprise single crystals of one or more semiconductor materials. Among other things, using such single crystal materials for semiconductor devices essentially eliminates the scattering of charged carriers (e.g., holes and electrons) at grain boundaries that exist in non-single crystal semiconductor materials such as poly-crystalline semiconductor materials. Such scattering adversely reduces the drift mobility and the diffusion of charged carriers, and leads to a degraded performance (e.g., increased resistance and decrease in optical to electrical conversion efficiency) of devices, such as transistors and solar cells. Even when different semiconductor materials were employed together in a single device, such as in a heterostructure or heterojunction device, single crystal semiconductor materials are generally chosen based on their respective lattice structures to insure that the structure realized is an essentially single crystal structure as a whole. Similarly, nanostructures including, but not limited to, nanowires and nanodots are typically nucleated and grown from single crystal substrates, in part to capitalize on the uniform nature of the lattice of such substrates that provides required crystallographic information for the nanostructures to be grown as single crystals.

Relatively recently, amorphous and other non-single crystal semiconductor materials have begun to attract attention, in particular, in solar cell applications, at least for potential cost savings. While having the disadvantages associated with multiple grain boundaries, such non-single crystal semiconductor materials can be considerably cheaper to manufacture than their single crystal counterparts. In many applications, the lower cost of producing the semiconductor device from non-single crystal materials outweighs any loss of performance that may result. Furthermore, using non-single crystal semiconductor materials for heterostructures can increase the possible combinations of materials that can be used since lattice mismatch is less of a concern with non-single crystal semiconductors.

While significant progress has been made in overcoming many of the practical challenges associated with producing high performance, lower cost solar cells, there is still a need for further lowering of the manufacturing cost and the material costs of such photovoltaic devices, especially to make solar cells more affordable and attractive to the average consumer and industry as a whole. A photovoltaic cell that is less expensive to manufacture and that does not compromise efficiency would satisfy a long felt need.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1A illustrates a cross sectional view of a photovoltaic cell, according to an embodiment of the present invention.

FIG. 1B illustrates a magnified cross sectional view of a photovoltaic structure of a photovoltaic cell, according to an embodiment of the present invention.

FIG. 1C illustrates a magnified cross sectional view of a photovoltaic structure of a photovoltaic cell, according to another embodiment of the present invention.

FIG. 1D illustrates a magnified cross sectional view of a photovoltaic structure of a photovoltaic cell, according to another embodiment of the present invention.

FIG. 2 illustrates a cross sectional view of a portion of a solar cell, according to an embodiment of the present invention.

FIG. 3A illustrates a flow chart of a method of fabricating a photovoltaic structure, according to an embodiment of the present invention.

FIG. 3B illustrates a flow chart of forming a stub of the method illustrated in FIG. 3A, according to an embodiment of the present invention.

FIG. 4A-4D illustrate cross sectional views of a photovoltaic structure being fabricated in accordance with the method illustrated in FIGS. 3A-3B, according to an embodiment of the present invention.

FIG. 5A-5E illustrate cross sectional views of a photovoltaic cell being fabricated in accordance with the method illustrated in FIGS. 3A-3B, according to another embodiment of the present invention.

### DETAILED DESCRIPTION

Embodiments of the present invention provide a photovoltaic structure for a photovoltaic cell that employs a nanowire and a self-aligned nanoscale fabrication approach to make the photovoltaic structure. In particular, the nanowire-based photovoltaic structure provides both built-in electrical isolation and a large contact area to reduce a series resistance of a photovoltaic cell comprising the photovoltaic structure, according to embodiments of the present invention. The nanowire provides greater surface area along its length for a semiconductor junction in the photovoltaic cell. In some embodiments, a plurality of nanowires that has a disordered arrangement in the photovoltaic cell further contributes to increasing the semiconductor junction contact area. Further, the disordered nanowires may facilitate more light absorption by the photovoltaic cell.

The nanoscale fabrication approach is a self-aligned process that uses no lithography at all or uses no multilayer precision lithographic techniques (e.g., having less than one micrometer alignment accuracy), such that fabrication cost may be reduced. Precision lithography can be complicated, time consuming and costly (reducing yield). In some embodiments, the fabrication process is also a relatively low temperature process, for example, below 400° C., which allows for a greater variety of materials to be used. Concomitantly, the nanoscale fabrication process provides a built-in isolation layer that reduces a number of process steps. The built-in isolation layer automatically isolates electrical connections between opposite ends of the nanowire. In some embodiments, non-single crystal materials are used to fabricate the photovoltaic cell. Non-single crystal materials not only may reduce cost of the photovoltaic cell, but also provide for a greater variety of materials to be used as well. Moreover, non-single crystal materials facilitate in providing the disordered arrangement of nanowires mentioned above for the nanowire-based photovoltaic cell of some embodiments. The large surface area and low series resistance facilitate using the nanowire-based photovoltaic cell in solar cell applications.

According to various embodiments, the photovoltaic structure of the present invention comprises a stub that is a constituent of a substrate surface. The stub is surrounded by an isolation layer but for an upper surface, which is connected to a nanowire. The nanowire extends from the upper surface of the stub in a direction away from the substrate surface. During fabrication of the photovoltaic structure, a nanoparticle is applied to the substrate surface. The nanoparticle provides a self-aligned mask for both formation of the stub and growth of the nanowire. The stub is formed by creating the isolation layer using the nanoparticle as a mask. In effect, the isolation layer is also self-aligned by the nanoparticle mask, as well as being built-in by the formation of the stub. The isolation layer that is created has a portion that embeds into the substrate surface and a portion that forms on the substrate surface. In addition, the embedded portion of the isolation layer undercuts the nanoparticle to a limited amount. As such, the stub that is formed in the substrate surface is narrower than the nanoparticle used as the mask. Moreover, the stub is at least as tall as the embedded portion of the isolation layer is thick as measured in a horizontal plane of the substrate.

In some embodiments, the stub is etched into the substrate surface using the nanoparticle as an etch mask before the isolation layer is created. In these embodiments, the stub is taller than the isolation layer is thick. When the isolation layer is created after the etched stub, the isolation layer not only embeds into the substrate surface, as mentioned above, but also embeds into sidewalls of the etched stub by undercutting the nanoparticle mask to surround the stub, also as mentioned above.

The nanoparticle also masks the upper surface of the stub while the isolation layer is created. The nanowire is grown from the upper surface of the stub using the nanoparticle to catalyze the nanowire growth. The nanoparticle remains on a tip or free end of the nanowire. The nanowire is at least as wide as a width of the nanoparticle and therefore, the nanowire is wider than the stub to which it is connected. As such, a portion of the nanowire adjacent to the stub overlies a part of the isolation layer that is adjacent to and surrounds the stub. The portion of the nanowire that overlies the isolation layer is either a base of the nanowire that is connected to the stub or an axial length segment of the nanowire adjacent to the nanowire base. In some embodiments, the nanowire may have a width that varies along the axial length of the nanowire. The shape and length of the nanowire are controlled during the nanowire growth process.

In some embodiments, the substrate is a single crystal semiconductor material and as such, the stub is a single crystal semiconductor constituent of the substrate surface. In other embodiments, the substrate is a non-single crystal material. In some of these embodiments, the substrate surface comprises a seed layer of a non-single crystal semiconductor material that has short range crystallographic information such that the substrate surface can nucleate nanowire growth from a crystallite in the seed layer. Therefore, the stub is a constituent of the non-single crystal semiconductor seed layer of the substrate in some embodiments. In other words, the upper surface of the stub, which is masked with the nanoparticle, provides a seed or a ‘crystallite’ for single crystal growth of the nanowire using the nanoparticle as a catalyst.

Using a non-single crystal material as a substrate and a non-single crystal semiconductor surface layer as a seed layer, according to some embodiments of the present invention, may provide cost and manufacturing advantages as well as performance advantages to the photovoltaic device. For example, a solar cell device that can be manufactured using non-single crystal materials (e.g., a glass substrate with microcrystalline silicon surface layer) interfaced to single crystal nanowires may be one or both of cost-effective to make and efficient. This may be so simply due to the fact that a greater variety of materials would be available for solar cell devices. Moreover, the greater variety of these available materials may provide for energy conversion from more of the solar spectrum than previously available, which may improve solar cell efficiency according to some embodiments.

A non-single crystal semiconductor seed layer has a plurality of crystallites that are disordered or non-uniform both in location in the layer and in crystal orientation. As such, a crystallite provided in the upper surface of the seed layer stub will dictate any one of a variety of directions that a respective nanowire will grow relative to a main horizontal plane of the substrate. In a plurality of such seed layer stubs of a substrate surface, the respective single crystal nanowires will grow in a variety of directions and appear disordered or non-uniform. In contrast, in a single crystal surface of a single crystal substrate, there is one crystal with a single crystal direction (e.g., [111] or [110]) perpendicular to the horizontal plane of the substrate. Therefore, the upper surface of a single crystal stub will dictate the direction with respect to the substrate surface that a respective nanowire will grow. In a plurality of such single crystal stubs of a single crystal substrate surface, a majority of the respective nanowires will grow in the same crystal direction and appear relatively ordered or uniform.

In some embodiments, the substrate surface is planar. In other embodiments, the substrate surface is non-planar, which may include either an irregular (i.e., uneven) surface or a surface having regular pattern of trenches, holes or bumps in the surface, for example. A stub formed in a non-planar substrate surface may have an upper surface that is oriented at an angle relative to a main horizontal plane of the substrate simply due to the location of the stub in the non-planar substrate surface, e.g., located in or on a side of a trench, a hole or a bump or an uneven spot. In some embodiments, the angle of the upper surface of the stub will also facilitate a direction that the nanowire will extend relative to the main horizontal plane of the substrate. For example, in a plurality of formed stubs, the greater the variety of angles that the upper surface of the stubs have, the more disorder there will be in the directions that respective nanowires will extend from the plurality of the stubs. As such, a single crystal substrate that would normally have nanowires grown from the surface thereof in a uniform direction may be made to have nanowires with relatively non-uniform growth directions using a non-planar single crystal substrate surface, according to some embodiments of the present invention.

Herein, a ‘seed layer’ is defined as a non-single crystal semiconductor material that has a microstructure with short range atomic ordering. In contrast, a ‘single crystal’ material has a crystal lattice microstructure with long-range atomic ordering that is continuous in micrometer scale. The short range atomic ordering of the seed layer manifests as multiple, small regions of crystalline material or ‘crystallites’ dispersed within and generally throughout the seed layer. Crystallites provide a template for potential nucleation and growth of a single crystal nanowire. The regions of crystallites may range from clusters of individual crystallites to discrete individual crystallites. Thus, by definition, the ‘seed layer’ comprises multiple crystallites buried in an amorphous matrix. Adjacent crystallites within the seed layer have respective lattices that are non-uniformly oriented with respect to one another. Further, crystallites adjacent to a surface of the seed layer are non-uniformly located across the surface.

A ‘microcrystalline’ semiconductor material is one type of a non-single crystal semiconductor material that has a microstructure with short range atomic ordering. Another non-single crystal semiconductor material is an ‘amorphous’ semiconductor material. The crystallites in the respective non-single crystal semiconductor materials define the short range atomic ordering of the material. For example, silicon may be deposited on a non-single crystal substrate as a microcrystalline silicon layer or an amorphous silicon layer, depending on the deposition conditions. By definition, each of such ‘microcrystalline’ semiconductor material and ‘amorphous’ semiconductor material has available crystallites to nucleate single crystal nanowire growth and are examples of non-single crystal semiconductor seed layer materials according to various embodiments of the invention. For simplicity of discussion, the term ‘microcrystalline’ may be used below to refer to the ‘non-single crystal semiconductor’ seed layer material on a surface of a non-single crystal substrate, as defined hereinabove. The term ‘microcrystalline’ is intended to collectively refer to one or both of a microcrystalline semiconductor material and an amorphous semiconductor material, as defined herein, unless otherwise stated.

As mentioned above, a crystallite of a seed layer substrate surface provides a template for potential nucleation and growth of a single crystal nanowire. The non-uniform orientations and distribution of the crystallites in the seed layer substrate surface means that a stub formed in seed layer surface may or may not have a crystallite or may have a portion of a crystallite or a cluster of crystallites. Nonetheless, the stub is smaller than the nanoparticle used in forming the stub and provides a potential seed surface for single crystal nanowire growth.

As used herein, the term ‘crystallite’ means a range of crystallites from a single crystallite to a group of crystallites aggregated together for the purposes of some embodiments. The crystallite provides a nucleation site for an epitaxial growth of the single crystal nanowire during fabrication of the photovoltaic structure. As such, the nanowires are also physically anchored to the crystallites in the upper surface of a seed layer stub. The grown nanowire forms an interface (e.g., a homojunction or a heterojunction) with the crystallite where the nanowire is connected to the crystallite commensurately. In some embodiments, the crystal lattice of the single crystal nanowire and the crystal lattice of the crystallite of the seed layer stub are coherent. As such, the nanowire is said to be ‘integral to’ a crystallite of the seed layer stub that nucleates the nanowire growth. The integral crystal-structure connection at the interface between the seed layer stub and the single crystal nanowire facilitates using the interface in semiconductor junction-related photovoltaic applications. The coherent lattices of the seed layer stub and the single crystal nanowire facilitate charge carrier transport through the interface, for example. For a single crystal stub and a single crystal nanowire, the lattices of the stub and the nanowire that is epitaxially grown thereon are coherent, by definition, and therefore facilitate charge carrier transport through the interface for semiconductor junction-related photovoltaic applications.

A ‘nanowire’ is an individual quasi-one dimensional, nano-scale structure characterized as having two spatial dimensions or directions that are much less than a third spatial dimension or direction. The presence of the third, greater dimension in nanowires facilitates electron wave functions along that dimension while conduction is quantized in the other two spatial dimensions. As used herein, the terra ‘nanowire’ is defined as a single-crystal semiconductor nano-scale structure, as described above, having an axial length (as a major or third spatial dimension), opposite ends and a solid core. A width of the nanowire also may be one of larger than, smaller than and the same size as the crystallite to which the nanowire is integrally attached. Where multiple crystallites are involved, the nanowire width may be one of larger than, smaller than and the same size as a length scale of the multiple crystallites over which the nanowire nucleates on the surface. Moreover, the nanowire may have dimensions from tens of nanometers to several hundred nanometers, for example; and the nanowire may not have the same dimension along the axial length of the nanowire, for example. As such, the nanowire may have a tapered shape or a non-tapered shape and such shape may be uniform or non-uniform along the axial length of the nanowire.

For simplicity herein, a ‘substrate surface’ may mean either a surface of a substrate or a seed layer of material on a surface of a substrate, depending on the embodiment of the present invention. The term ‘optically transparent’ is defined herein as being either transparent or semi-transparent to electromagnetic radiation in one or more of visible, UV and IR spectrums. Further, as used herein, the article ‘a’ is intended to have its ordinary meaning in the patent arts, namely ‘one or more’. For example, ‘a nanowire’ generally means one or more nanowires and as such, ‘the nanowire’ means ‘the nanowire(s)’ herein. Also, any reference herein to ‘top’, ‘bottom’, ‘upper’, ‘lower’, ‘up’, ‘down’, ‘left’ or ‘right’ is not intended to be a limitation herein. Moreover, examples herein are intended to be illustrative only and are presented for discussion purposes and not by way of limitation.

The use of brackets ‘[ ]’ herein in conjunction with such numbers as ‘111’ and ‘110’ pertains to a direction or orientation of a crystal lattice and is intended to include a set of equivalent directions ‘< >’ within its scope, for simplicity herein. The use of parenthesis ‘( )’ herein with respect to such numbers as ‘111’ and ‘110’ pertains to a plane or a planar surface of a crystal lattice and is intended to include planes of equivalent symmetry ‘{ }’ within its scope for simplicity herein. Such uses are intended to follow common crystallographic nomenclature known in the art.

Further and by way of definition, reference herein to a layer being ‘embedded in and on a substrate surface’ is defined to mean a layer that is formed by consuming some of the substrate material near the substrate surface during formation of the layer. A portion of the layer is embedded in the original substrate surface and a portion lies on the original substrate surface, i.e., the ‘surface portion’ of the layer overlies the ‘embedded portion’. The portions of the layer use the substrate material to form the layer. According to the various embodiments herein, the built-in isolation layer is ‘embedded in and on a substrate surface’. For example, the isolation layer may be an oxide of the semiconductor material of the substrate surface. A portion of the oxide layer is embedded in the semiconductor surface. Another portion of the oxide layer is formed over the embedded portion as the semiconductor material of the substrate surface is consumed.

The term ‘extrinsic semiconductor’ is defined as a semiconductor material that is intentionally doped with either a p-type dopant or an n-type dopant to provide a higher level of electrical conductivity to the semiconductor material than the semiconductor inherently has. The term ‘extrinsic region’ is a region of the extrinsic semiconductor). The term ‘intrinsic semiconductor’ is defined as a semiconductor material that is either undoped, lightly doped, or not intentionally doped with a dopant material. The term ‘intrinsic region’ is a region of the intrinsic semiconductor. By ‘lightly doped’ and ‘not intentionally doped’ (or ‘unintentionally doped’), it is meant that a relatively small amount of dopant may be incorporated in the intrinsic semiconductor, for example as a result of doping an extrinsic semiconductor. The relatively small amount of dopant is a very low concentration of dopant, for example approximately 10¹⁵ per cubic centimeter, relative to an extrinsically doped semiconductor, which may have 10¹⁷ per cubic centimeter of dopant or higher, for example.

According to the various embodiments herein, the photovoltaic cell comprises a semiconductor junction provided by selective doping one or both of within or between the structures or layers of the cell. The term ‘semiconductor junction’ includes within its scope, a p-n junction, a p-i-n junction and a Schottky junction. For example, a p-n junction may be formed in a photovoltaic structure when the nanowire is an extrinsic semiconductor doped with an n-type dopant and the stub and the substrate surface are an extrinsic semiconductor doped with a p-type dopant. In another example, a p-n junction is formed entirely by or within an extrinsic semiconductor nanowire. A Schottky junction may be formed between a semiconductor substrate and a metal electrical contact of the photovoltaic cell, for example.

In some embodiments, an intrinsic region is formed between a p-region and an n-region to yield a p-i-n junction within the photovoltaic cell. For example, the stub may be a p-doped extrinsic semiconductor, a conformal coating on the nanowire may be an n-doped extrinsic semiconductor, and the nanowire is an intrinsic semiconductor, as defined above. The intrinsic semiconductor nanowire connects between the extrinsic semiconductor stub and the extrinsic semiconductor conformal coating to form the intrinsic region ‘i’ of a p-i-n junction. The p-i-n junction is formed all along the axial length of the nanowire that is in contact with the extrinsic semiconductor conformal coating. In another example, the nanowire may comprise an intrinsic region in an axial segment of the nanowire length and an extrinsic region in adjacent axial length segment that is p-doped or n-doped), depending on the doping of the structure or layer (i.e., the stub or semiconductor coating) which is adjacent to doped axial length segment of the nanowire.

In another embodiment, a p-i-n junction may be formed concentrically along the axial length of the nanowire. For example, a nanowire core may be an extrinsic semiconductor region having a p-type dopant that is integral to a p-type doped stub; an inner conformal layer on the nanowire core may be an intrinsic semiconductor region; and an outer conformal layer on the inner conformal layer may be an extrinsic semiconductor region having an n-type dopant. In other embodiments, multiple p-n junctions, p-i-n junctions and combinations thereof are formed in or between the nanowire, the stub and a semiconductor conformal coating.

Moreover, the level of doping in each layer or structure may be the same or different. The variation in dopant level may yield a dopant gradient, for example. In an example of differential doping, one or both of the stub and the semiconductor conformal coating on the nanowires may be heavily doped to yield a p+ region providing a low resistivity within the respective structure or layer, while an adjacent axial length segment of the nanowire may be less heavily p-doped to yield p region. In another example, the substrate surface and the stub may be p-doped while a remainder of the substrate may be p+ doped. The p+ region of the substrate may be adjacent to an external electrical contact of the photovoltaic cell.

According to some embodiments, the photovoltaic cell may comprise a heterostructure or a heterojunction. For example, semiconductor materials having differing band gaps are employed to respectively realize the single crystal nanowire and the semiconductor materials of the substrate surface and the conformal coating on the nanowires. The photovoltaic cell that comprises such differing materials is termed a heterostructure photovoltaic cell. Further, according to some embodiments, the photovoltaic cell may be a hetero-crystalline photovoltaic cell. The term ‘hetero-crystalline’ is defined herein as a structure comprising at least two different types of structural phases. For example, the photovoltaic cell that comprises a microcrystalline stub and a single crystal nanowire, according to some embodiments, is a hetero-crystalline photovoltaic cell.

The material of the substrate includes, but is not limited to, a glass, a ceramic, a metal, a plastic, a polymer, a dielectric and a semiconductor. A substrate material useful for the various embodiments herein includes materials having either a non-single crystal structure or a single crystal structure. A non-single crystal structure includes, one of a relatively unidentifiable or no crystallographic structure (e.g., glass), a microcrystalline structure (i.e., having short range atomic order, as defined herein, that includes amorphous semiconductors), a polycrystalline structure (i.e., having short range atomic order of relatively greater extent than a microcrystalline structure). The single crystal structure has relatively long range atomic order. In some embodiments, the substrate material may be chosen at least for its ability to withstand manufacturing temperatures. In various embodiments, the substrate may be one of rigid, semi-rigid and flexible, depending on specific applications of the photovoltaic structure. Moreover, the substrate may exhibit one or more of the following characteristics: thermally conductive, electrically conductive, refractive, reflective, opaque, and optically transparent, depending on the embodiment of the photovoltaic structure.

A non-single crystal material includes, but is not limited to, an insulator, a semiconductor, a metal and a metal alloy. For the purposes of the various embodiments of the present invention, the substrate surface seed layer herein is a semiconductor material. The semiconductor seed layer material includes, but is not limited to, Group IV semiconductors, compound semiconductors from Group III-V and compound semiconductors from Group II-VI having a microcrystalline structure, as defined herein. For example, the substrate surface seed layer may comprise one of silicon (Si), germanium (Ge) and gallium arsenide (GaAs) in either a microcrystalline film or amorphous film layer while the substrate may be glass. In another example, the substrate surface seed layer may comprise either a microcrystalline hydrogenated silicon (‘mc-Si:H’) film or an amorphous hydrogenated silicon (‘a-Si:H’) film. The Si:H films may be doped either p-type or n-type, depending on the embodiment of the photovoltaic structure.

In some embodiments, the photovoltaic structure further comprises a conformal coating on the nanowire. The conformal coating has one of an amorphous structure, a microcrystalline structure, and a single crystal structure and includes, but is not limited to, a semiconductor material, a metal, a transparent conductive oxide and a silicide. In some embodiments, the conformal coating is a semiconductor material that includes, but is not limited to, a Group IV semiconductor, a compound semiconductor from Group III-V and a compound semiconductor from Group II-VI. For example, a semiconductor conformal coating comprises a highly doped single crystal semiconductor layer grown on the sidewalls of the nanowire. In another example, the semiconductor coating comprises a highly doped polycrystalline silicon or an amorphous hydrogenated silicon (‘a-Si:H’) film deposited on the nanowire.

In some embodiments, the semiconductor conformal coating is grown on the nanowire either during nanowire growth or after nanowire growth. When the semiconductor conformal coating is grown during nanowire growth, the conformal coating is single crystal, covers the axial length of the nanowire and remains under the nanoparticle. When the conformal coating is deposited after nanowire growth, the conformal coating covers the axial length of the nanowire and also covers the nanoparticle. In some embodiments, the nanoparticle may be removed prior to the conformal coating. A conformal coating deposited after nanowire growth may be either single crystal semiconductor or a non-single crystal semiconductor. Moreover, doping of the conformal coating may be varied to create intrinsic and extrinsic layers in the conformal layer, such as that described above for concentrically formed semiconductor junctions.

In some embodiments, the conformal coating is a metal that includes, but is not limited to, gold, silver, platinum, palladium, tin, aluminum and copper. The metal conformal coating on the nanowire forms a Schottky contact with the semiconductor nanowire, for example. In some embodiments, the conformal coating is a conductive oxide, which may or may not also be a semiconductor, that includes, but is not limited to, indium tin oxide (ITO) and zinc oxide (ZnO). In other embodiments, the conformal coating is a silicide or a germanide that includes, but is not limited to, platinum silicide (PtSi).

Single crystal semiconductor materials, such as those used for the nanowire and the single crystal substrate, according to some embodiments, independently include, but are not limited to, Group IV semiconductors, compound semiconductors from Group III-V and compound semiconductors from Group II-VI. Therefore, the single crystal semiconductor material of the nanowire may be the same as or different from the semiconductor substrate, the semiconductor substrate surface and the respective stub and the conformal coating, depending on the embodiment. For example, the single crystal substrate and the respective surface and stub may be single crystal silicon (Si) and the nanowire may be single crystal indium phosphide (InP). In another example, the substrate may be glass, the substrate surface seed layer and the respective stub may be a microcrystalline silicon (‘mc-Si’) (or an amorphous silicon (‘a-Si’, depending on the embodiment), while the nanowire may be indium phosphide (InP). In either of these examples, a conformal coating on the InP nanowire may comprise one or both of a single crystal semiconductor and a non-single crystal semiconductor, depending on the embodiment. For example, a conformal coating of silicon may conformally coat the single crystal InP nanowire.

In some embodiments, concomitant with a choice of the semiconductor materials independently used in the photovoltaic cell is a respective energy band gap of the respective materials. In some embodiments where the conformal coating is a semiconductor material, the energy band gap of the nanowire is different from the energy band gap of one or both of the semiconductor stub and the semiconductor conformal coating. In some embodiments, the energy band gap of the semiconductor stub is different from the energy band gap of the semiconductor conformal coating. In other embodiments, the energy band gaps of the stub and the semiconductor conformal coating are the same. Using materials with different energy band gaps makes the photovoltaic cell a heterostructure device.

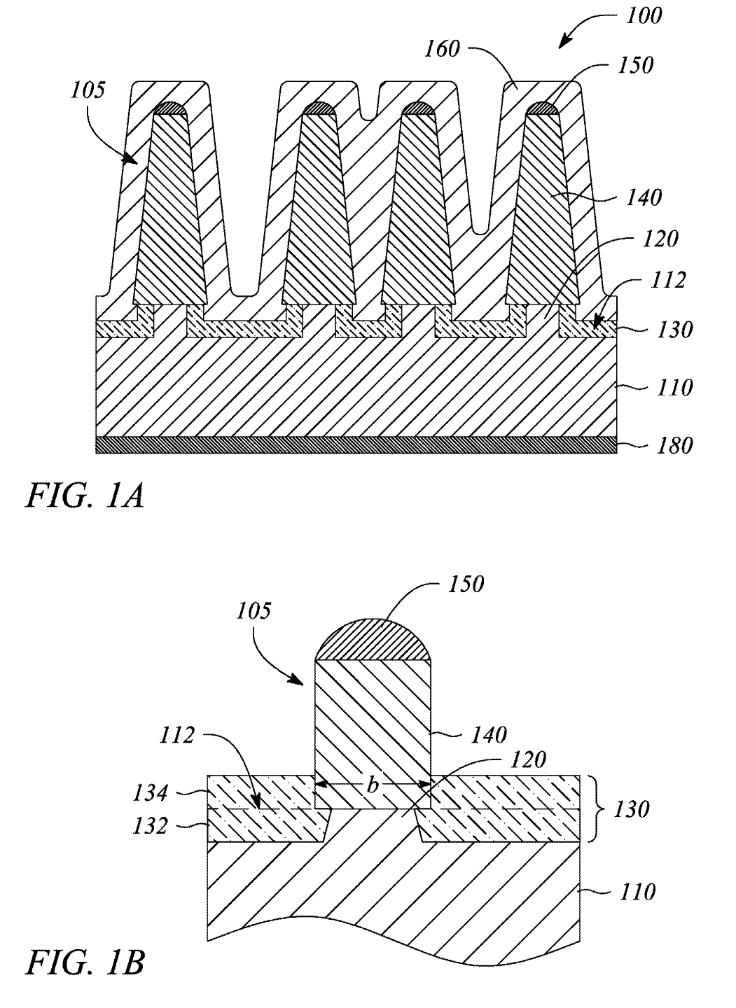

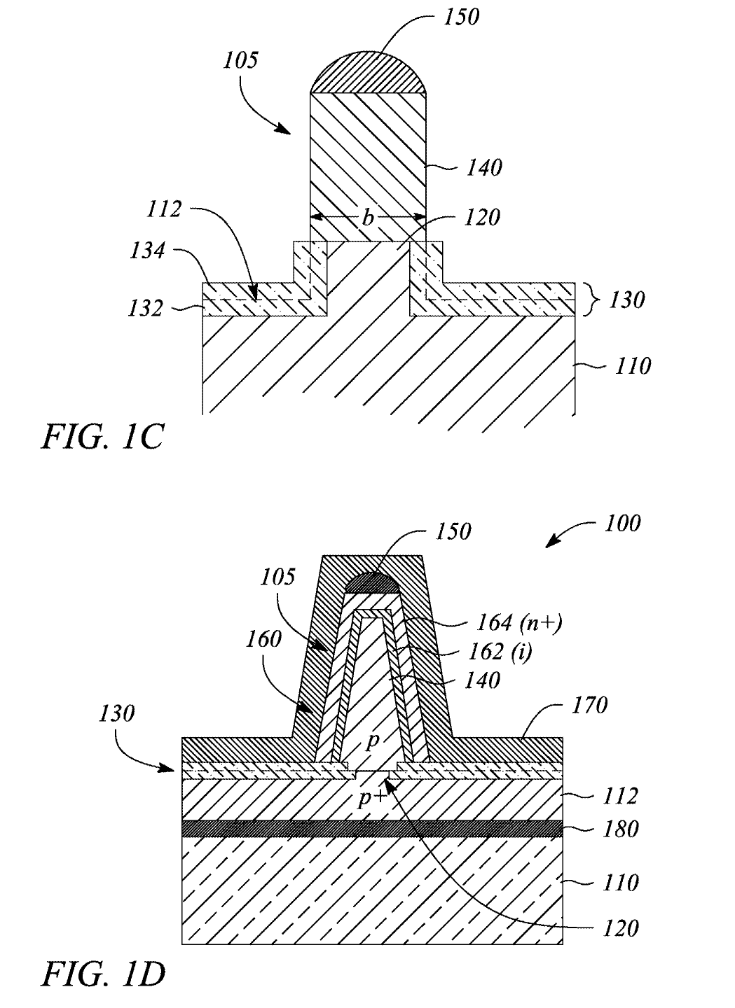

In some embodiments of the present invention, a photovoltaic structure is provided. FIG. 1A illustrates a cross sectional view of a photovoltaic cell 100 that comprises the photovoltaic structure 105, according to an embodiment of the present invention. FIGS. 1B and 1C illustrate magnified cross sectional views of photovoltaic structures 105 of a photovoltaic cell according to various embodiments herein. The photovoltaic cell 100 comprises a substrate 110 having a substrate surface 112. The substrate surface 112 comprises an extrinsic semiconductor having either a p-type dopant or an n-type dopant (not illustrated in FIG. 1A), as defined above. The photovoltaic cell 100 further comprises a stub 120 that is a constituent of the substrate surface 112. Therefore, the stub 120 comprises the extrinsic semiconductor of the substrate surface 112. Four stubs 120 are illustrated in FIG. 1A by way of example. Any number in a plurality of stubs may be present in the various embodiments illustrated herein.

As defined above, the substrate 110 and the substrate surface 112 may be indistinguishable materials in some embodiments. In other words, in some embodiments, the substrate 110 may be a single crystal semiconductor and the surface 112 may be the surface of the single crystal semiconductor substrate 110. In other embodiments, the substrate 110 and the substrate surface 112 may be distinguishable materials. For example, the substrate 110 may be an amorphous material and the substrate surface 112 may be a microcrystalline semiconductor seed layer. In the embodiment illustrated in FIG. 1A, the substrate 110 and the substrate surface 112 are both a single crystal semiconductor by way of example.

The photovoltaic cell 100 further comprises an electrical isolation layer 130 that surrounds the stub 120. Not illustrated in FIG. 1A, the isolation layer 130 comprises two portions. The magnified views of FIGS. 1B and 1C illustrate a first portion 132 of the isolation layer 130 is embedded (i.e., ‘embedded portion 132’) in the substrate surface 112, while a second portion 134 (i.e., ‘surface portion 134’) of the isolation layer 130 is on the embedded portion 132 or effectively, on the original substrate surface 112 (delineated by a horizontal dashed line) of the respective photovoltaic structures 105. In FIGS. 1A and 1C, the stub 120 is taller than the isolation layer 130 is thick in a horizontal plane of the substrate. As such, the isolation layer 130 also extends in and on sidewalls of the stub 120 to surround the stub 120, as well as in and on the relatively horizontal substrate surface 112 between the stubs 120. The sidewalls of the stub 120 may be relatively vertical, as illustrated in FIG. 1C by way of example, or may be tapered in that a lower portion of the stub is wider than an upper portion of the stub, as illustrated by way of example in FIG. 1B.

The photovoltaic cell 100 further comprises a nanowire 140 connected to an upper surface of the stub 120. The nanowire 140 is integrally connected to the stub 120, as defined herein. The nanowire 140 comprises one or both of an intrinsic semiconductor and an extrinsic semiconductor, as defined above, depending on the embodiment. The nanowire 140 further comprises a nanoparticle 150 at a tip or free end of the nanowire 140. The free end is opposite a base end of the nanowire 140 that is attached to the stub 120. The nanoparticle comprises a metal including, but not limited to, titanium (Ti), platinum (Pt), nickel (Ni), gold (Au), gallium (Ga), and alloys thereof. The nanoparticle is a catalyst material that catalyzes nanowire growth, as described further below.

As illustrated in FIG. 1A, the nanowire 140 has a conical or tapered shape that is wider adjacent to the nanowire base and narrower at the nanowire tip, according to some embodiments. The shape of the nanowire 140 is not limited to the illustrated shape and, as described above, the nanowire may have any number of shapes along its axial length from a regular columnar shape to an irregular taper shape. Notwithstanding the variety of shapes of the nanowire 140, according to the various embodiments herein, the nanowire 140 is wider than a width of the stub 120 and the nanowire 140 overlies the isolation layer 130 in a vicinity adjacent to the stub 120. This is so for two reasons: first, the stub is narrower than the nanoparticle 150; and second, the nanowire 140 is at least as wide as the nanoparticle 150. As such, the base of the nanowire 140 overlies the embedded portion 132 of the isolation layer 130 adjacent to the stub 120. In some embodiments, the nanowire or a portion thereof overlies the surface portion 134 of the isolation layer 130. In other embodiments, the base of the nanowire 140 may overlie both portions 132, 134 of the isolation layer 130 adjacent to the stub 120. FIG. 1A illustrates that the base of the nanowire 140 overlies and further overhangs the isolation layer 130, in some embodiments.

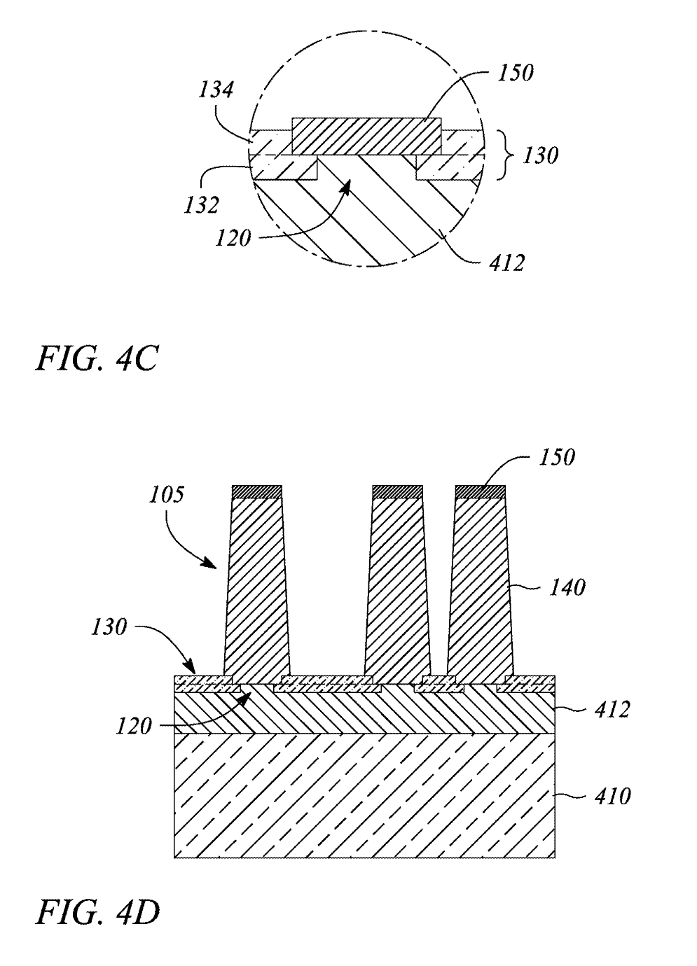

In the embodiment of the photovoltaic structure 105 illustrated in FIG. 1B, the stub 120 is as tall as a thickness of the embedded portion 132 of the isolation layer 130. In this embodiment, the base b of the nanowire 140 extends from the upper surface of the stub 120 at a width approximately equal to the width of the nanoparticle 150. As such, the nanowire base b overlies a part of the embedded portion 132 of the isolation layer 130 that is adjacent to the stub 120. The nanowire 140 retains this width at least for a distance or height approximately equal to a thickness of the surface portion 134 of the isolation layer 130. Above the thickness of the isolation layer surface portion 134, the shape of the nanowire 140 may remain relatively the same for the axial length of the nanowire, as illustrated in FIG. 1B, by way of example, or may be wider in at least an adjacent axial length segment of the nanowire 140 above the base b. An illustration of the wider axial segment of the nanowire 140 above the nanowire base is illustrated in FIG. 4D, which is described further below. As such, an axial segment of the nanowire 140 adjacent to and above the nanowire base may overlie a surrounding part of the surface portion 134 of the isolation layer 130 adjacent to the stub 120, in some embodiments.

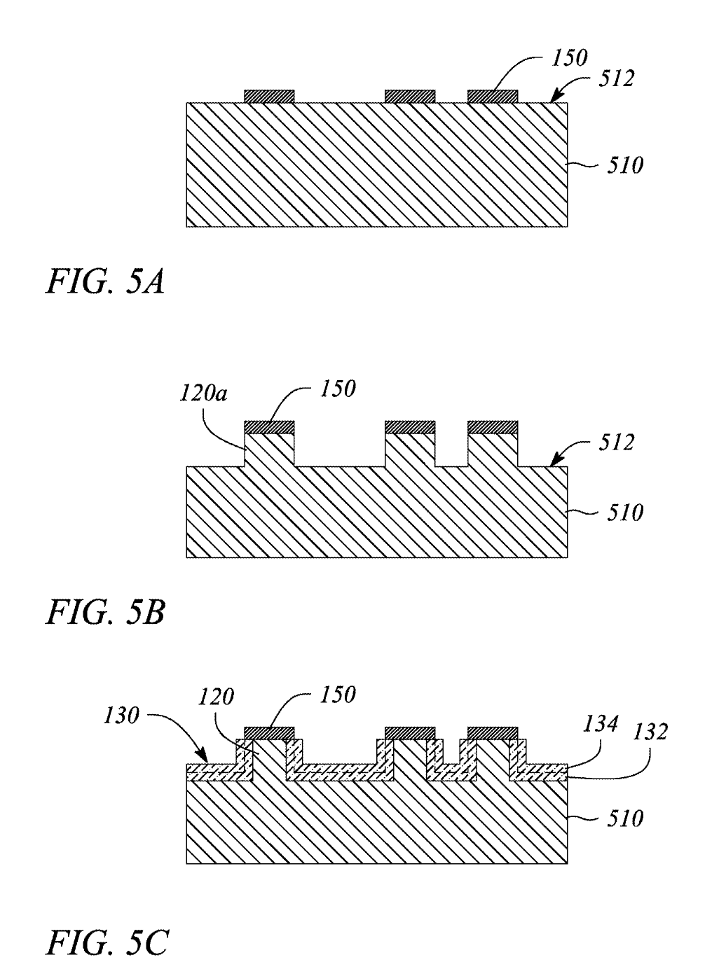

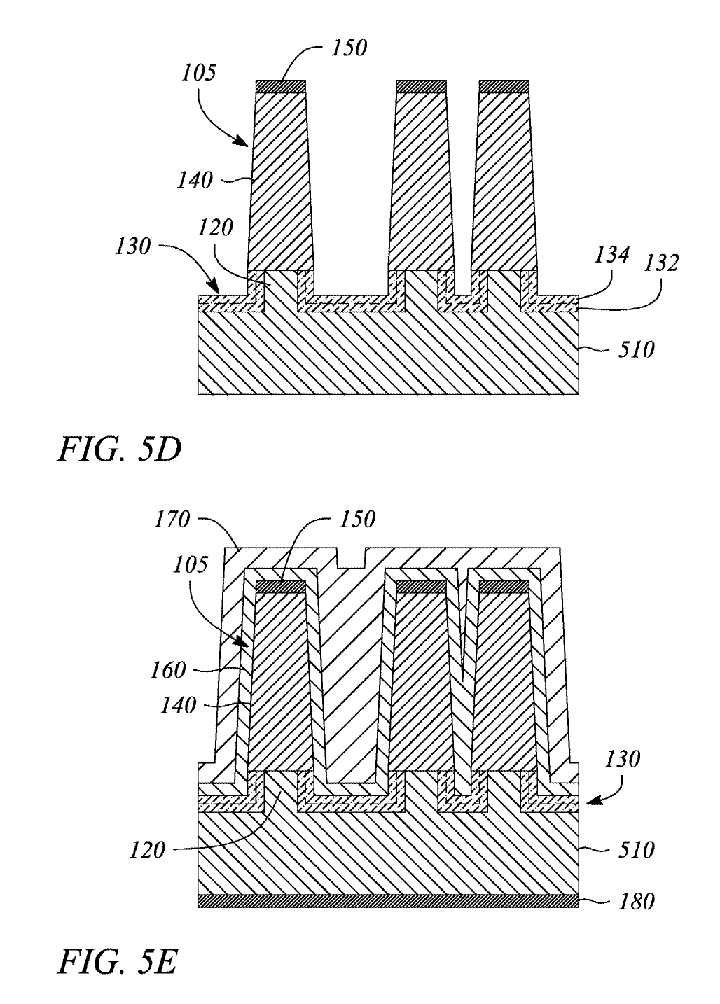

In the embodiment illustrated in FIG. 1C, the stub 120 is as tall as, or may be taller than, a thickness of the isolation layer 130. In either case, the isolation layer 130 extends along sidewalls of the stub 120. In this embodiment, the base b of the nanowire 140 still extends from the upper surface of the stub 120 at a width approximately equal to the width of the nanoparticle 150. Moreover, in this embodiment, the nanowire base b either overlies a relatively vertical part of the embedded portion 132 of the isolation layer 130 only, as illustrated in FIG. 1C, or overlies the relatively vertical parts of both portions 132, 134 of the isolation layer 130 adjacent to and surrounding the stub 120, as illustrated in FIG. 5E and described below. The relatively vertical parts are in relation to a horizontal plane of the substrate.

In some embodiments, the photovoltaic cell 100 further comprises an electrically conductive conformal layer 160 on the nanowire. The conformal layer 160 conformally coats the nanowire 140, and in some embodiments, conformally coats the isolation layer 130 around and between the nanowires 140, as illustrated in FIG. 1A by way of example. As such, the conformal layer 160 follows contours of the nanowire 140 along the axial length of the nanowire 140. In some embodiments, the conformal layer 160 comprises an extrinsic semiconductor, as defined above, having either a p-type dopant or an n-type dopant that is other than the dopant type of the extrinsic semiconductor of the substrate surface 112 and the stub 120. The conformal layer 160 is either sufficiently thin to be relatively optically transparent while being electrically conductive or is both electrically conductive and inherently an optically transparent material. As such, a semiconductor junction is provided between the conformal layer 160 and the semiconductor nanowire 140, along the axial length of the nanowire 140 where the conformal layer 160 is in contact with the nanowire 140. This large contact area may facilitate a low series resistance of the photovoltaic cell 100.

Further, in these embodiments, the isolation layer 130 electrically isolates the conformal layer 160 from the stub 120 and the substrate surface 112. In some embodiments, the nanowire 140 facilitates in the isolation between the conformal layer 160 and the stub 120 by physically separating the conformal layer 160 from the stub 120 at or near the base of the nanowire 140 where the nanowire 140 overlies the isolation layer 130 adjacent to the stub 120, as described above.

In some embodiments, the conformal layer on the nanowire comprises concentric conformal sublayers that form a concentric p-i-n junction with the nanowire. FIG. 1D illustrates a magnified cross sectional view of a photovoltaic structure 105 of a photovoltaic cell 100 according to another embodiment of the present invention. The photovoltaic structure 105 comprising an extrinsic semiconductor nanowire 140 integrally attached to an extrinsic semiconductor stub 120. The stub 120 is a constituent of an extrinsic semiconductor surface seed layer 112 on a non single crystal substrate 110. The surface seed layer 112 is one of a microcrystalline semiconductor and an amorphous semiconductor with short range atomic order, as defined above. The photovoltaic structure 105 further comprises an electrical isolation layer 130 surrounding the stub 120. The nanowire 140 overlies the isolation layer 130. The photovoltaic structure 105 further comprises a conformal layer 160 that covers just the nanowire 140. In the illustrated embodiment, the nanoparticle 150 remains above the conformal layer 160.

The conformal layer 160 in FIG. 1D comprises a first semiconductor sublayer 162 adjacent to and covering the extrinsic nanowire 140 and a second semiconductor sublayer 164 adjacent to and covering the first semiconductor sublayer 162. A base of the respective sublayers 162, 164 overlie the electrical isolation layer 130 at a periphery of the nanowire base 140. In the embodiment illustrated in FIG. 1D, the first semiconductor sublayer 162 is a single crystal semiconductor that comprises an intrinsic semiconductor. Moreover, the second semiconductor sublayer 164 is a single crystal semiconductor that comprises an extrinsic semiconductor. In other embodiments (not illustrated in FIG. 1D), the second semiconductor sublayer 164 may be a non-single crystal semiconductor material, such as an amorphous semiconductor, that further conformally covers the nanoparticle.

In the embodiment illustrated in FIG. 1D, the substrate surface layer 112 comprises a p+-type dopant and the nanowire comprises a p-type dopant. Moreover, the first conformal sublayer 162 forms an intrinsic ‘i’ region that surrounds the nanowire 140; and the second conformal sublayer 164 comprises an n+-type dopant. As such, a concentric p-i-n junction is created between the nanowire 140 and the sublayers 162, 164 of the conformal coating 160 along the axial length of the nanowire 140.

In some embodiments, the photovoltaic cell 100 further comprises electrical contacts that access opposite ends of the nanowire 140 (i.e., the tip or free end and the base) external to the photovoltaic structure 105. A first or top electrical contact provides access to the free end of the nanowire 140 and is, or is adjacent to, the conformal layer 160, depending on the embodiments. In some embodiments, FIG. 1A illustrates a photovoltaic cell 100 embodiment where the conformal coating 160 is also the top electrical contact. In other embodiments, the top electrical contact contacts the conformal coating 160 at a periphery of the photovoltaic cell 100 and therefore is not illustrated in FIG. 1A. A second or bottom electrical contact 180 is adjacent to the substrate 110 to access the base of the nanowire 140. In the embodiment illustrated in FIG. 1A, the substrate 110 and the substrate surface 112 are a single crystal extrinsic semiconductor. The bottom electrical contact 180 is illustrated on a side of the substrate 110 opposite to the side comprising the stubs 120. The bottom electrical contact 180 provides an external electrical connection to the nanowire 140 base by way of the extrinsic semiconductor substrate, in this embodiment.

For the photovoltaic cell 100 embodiment illustrated FIG. 1D, a first electrical contact 170 on top of the photovoltaic structure 105 covers the semiconductor conformal layer 160, the nanoparticle 150 and the isolation layer 130 to provide the external electrical connection to the nanowire 140 free end and while not illustrated in FIG. 1D, to provide an interconnection between adjacent nanowires of the photovoltaic cell. Moreover, a second electrical contact 180 is illustrated below the extrinsic semiconductor surface layer 112 and between the surface layer 112 and the non-single crystal substrate 110 to provide the external electrical connection to the nanowire 140 base, according to this embodiment of the photovoltaic cell 100.

The first and second electrical contacts are independently an electrically conductive material including, but not limited to a metal (e.g., aluminum (Al)), a transparent conductive oxide (e.g., indium-tin-oxide (ITO) or zinc oxide (ZnO)), a silicide (e.g., platinum silicide (PtSi)) and a highly doped semiconductor material (e.g., highly doped polycrystalline silicon (i.e., ‘poly-Si’). An optically transparent first electrical contact may cover the top of the photovoltaic structure in some embodiments, or in other embodiments, may encapsulate the structure. A non-optically transparent first electrical contact may be located on a peripheral surface of an interconnecting conformal layer so not to block light from the nanowires 140.

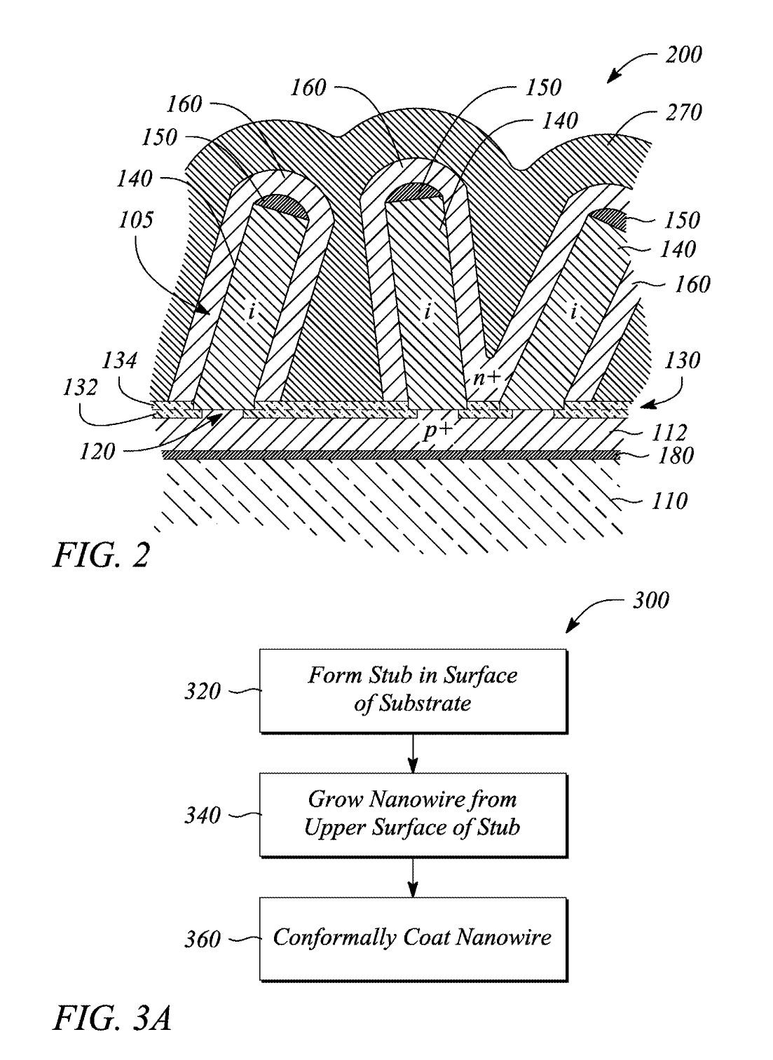

FIG. 2 illustrates a side view of a portion of a solar cell 200 according to another embodiment of the present invention. The solar cell 200 is an embodiment of the photovoltaic cell 100 described above. In the embodiment illustrated in FIG. 2, the solar cell 200 comprises a substrate 110 having a surface that comprises a microcrystalline surface layer 112. The substrate 110 is a non-single crystal material, including, but not limited to, glass, a polymer and a metal foil, for example. The microcrystalline surface layer 112 is an extrinsic, microcrystalline semiconductor material including, but not limited to, a microcrystalline silicon that is hydrogenated (‘mc-Si:H’), for example. The solar cell 200 further comprises a plurality of microcrystalline stubs 120 formed of the microcrystalline surface layer 112. The microcrystalline stubs 120 are non-uniformly located in the microcrystalline surface layer 112. In FIG. 2, the microcrystalline surface layer 112 and the microcrystalline stubs 120 are doped with a p+-type dopant, by way of example.

The solar cell 200 further comprises an isolation layer 130 which is the same as the isolation layer 130 described above for the photovoltaic cell 100. A dashed horizontal line within the isolation layer 130 represents an original surface of the microcrystalline surface layer 112 and delineates the embedded portion 132 and the surface portion 134 of the isolation layer 130, by way of example. In the illustrated embodiment, the microcrystalline stubs 120 are as tall as the embedded portion 132 of the isolation layer 130 is thick.

The solar cell 200 further comprises a plurality of nanowires 140, which are basically equivalent to the nanowires 140 described above for the photovoltaic cell 100. In the illustrated embodiment in FIG. 2, the nanowires 140 comprise an intrinsic semiconductor (i.e., ‘i’ in FIG. 2), as defined herein. Only three nanowires 140 and only three corresponding microcrystalline stubs 120 are illustrated in FIG. 2 for simplicity of illustration only. The nanowires 140 comprise a nanoparticle 150 at free ends of the nanowires 140. Since the nanowires 140 are grown from the microcrystalline stubs 120, the nanowires 140 of the plurality grow in a variety of different directions from the microcrystalline stubs 120 depending on the different crystallite(s) at the upper surface of the microcrystalline stubs 120. As such, the nanowires 140 grow at a variety of different angles measured from a main horizontal plane of the substrate 110. The result is a disordered or non-uniform array of nanowires 140, as compared to the embodiment illustrated in FIG. 1A, where the stubs 120 are single crystal and the nanowires 140 extend relatively uniformly from the substrate surface 112.

The solar cell 200 further comprises a conformal layer 160 that follows the contours of the disordered array of nanowires 140. The conformal layer 160 is equivalent to the semiconductor conformal layer 160 described above for some embodiments of the photovoltaic cell 100. In some embodiments, the conformal layer 160 covers only the nanowires and the nanoparticle at its free end, as illustrated in FIG. 2 by way of example, and may not also cover all of the isolation layer 130 between and around the nanowires 140. The conformal layer 160 is thick enough to conformally coat the surfaces of the plurality of disordered nanowires. In some embodiments, the conformal layer 160 is also thin enough to be relatively optically transparent. In other embodiments, the conformal layer 160 is also an optically transparent material. In the embodiment illustrated in FIG. 2, the conformal layer 160 is an extrinsic semiconductor that comprises an n+ dopant, by way of example, since the microcrystalline stubs 120 are p+ doped in this example. As such, all along the interface between the nanowires 140 and the semiconductor conformal layer 160 a p-i-n junction is formed with the microcrystalline stubs 120. In some embodiments, an intrinsic region is formed throughout the nanowire 140 volume. It is within the scope of the embodiments or any of the examples described herein for the dopant types to be reversed with respect to the p-type dopant and the n-type dopant.

In some embodiments, the solar cell 200 further comprises a top electrical contact. FIG. 2 illustrates a top electrical contact layer 170 on the conformal semiconductor layer 160 by way of example. The top electrical contact layer 170 interconnects the conformal layer 160 on spaced apart nanowires 140 in the embodiment illustrated in FIG. 2. The solar cell 200 further comprises a bottom electrical contact 180 in the embodiment of FIG. 2. The bottom electrical contact 180 is illustrated between the substrate 110 and the microcrystalline surface layer 112. In some embodiments, the bottom electrical contact 180 may be located on the substrate 110 adjacent and electrically connected to the microcrystalline surface layer 112 but not necessarily underneath the microcrystalline surface layer 112. In some embodiments, an electrically conductive material may be coated on all surfaces of the substrate 110 to provide electrical access to the base of the nanowires 140 by way of the extrinsic microcrystalline layer 112 and stubs 120. The top electrical contact 170 and the bottom electrical contact 180 are respectively similar to the first electrical contact 170 and the second electrical contact 180 described above for some embodiments of the photovoltaic cell 100.

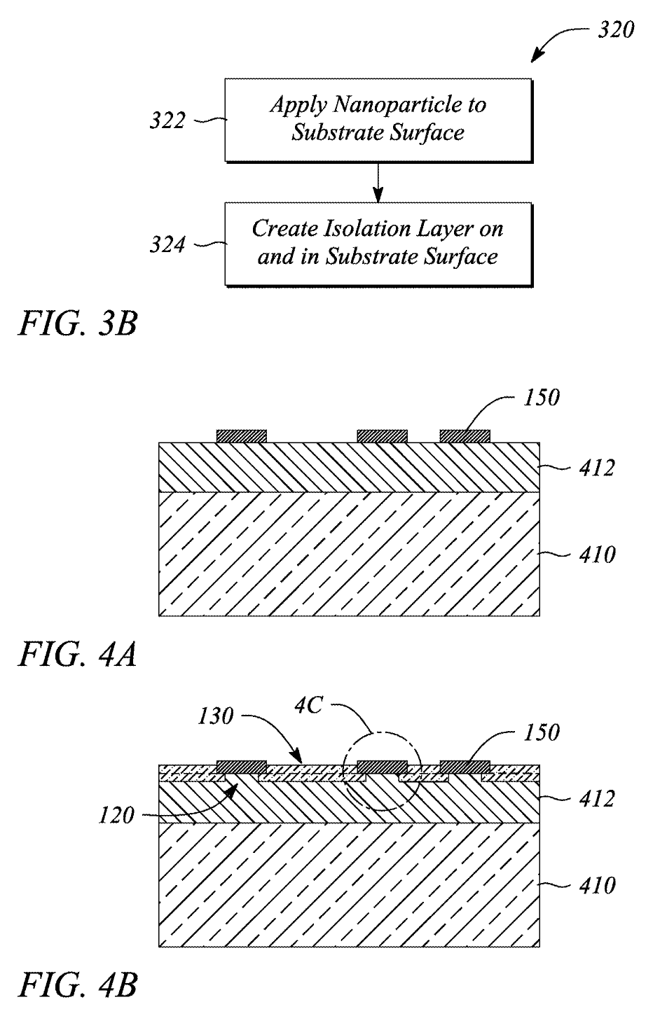

In another embodiment of the present invention, a method of fabricating a photovoltaic structure is provided. FIG. 3A illustrates a flow chart of a method 300 of fabricating a photovoltaic structure according to an embodiment of the present invention. The method 300 of fabrication is a self-aligned process for fabricating a nanowire-based photovoltaic cell, such as a solar cell. FIGS. 4A-4D illustrate cross sectional views of a photovoltaic structure during fabrication according to an embodiment of the present invention. FIGS. 5A-5E illustrate cross sectional views of a photovoltaic cell during fabrication according to another embodiment of the present invention.

Referring to FIG. 3A, the method 300 of fabricating a photovoltaic structure comprises forming 320 a stub in a surface of a substrate. The substrate surface comprises an extrinsic semiconductor and therefore, the formed stub is a constituent of the extrinsic semiconductor of the substrate surface. The method 300 of fabricating further comprises growing 340 a nanowire from an upper surface of the stub. The nanowire comprises one or both of an intrinsic semiconductor and an extrinsic semiconductor. In some embodiments, the intrinsic semiconductor extends the axial length of the nanowire, such that the volume of the nanowire is an intrinsic region. In other embodiments, an axial segment of the nanowire comprises an intrinsic semiconductor region, while another axial segment of the nanowire that is adjacent to the intrinsic axial segment comprises an extrinsic semiconductor region. Alternatively, in some embodiments, an extrinsic semiconductor extends the axial length of the nanowire. In some of these embodiments, the nanowire further comprises a concentric intrinsic region along the axial length of the nanowire (e.g., a core-shell nanowire structure).

According to the various embodiments herein, forming 320 a stub in the substrate surface employs a nanoparticle as a self-aligning mask. FIG. 3B illustrates a flow chart of forming 320 a stub according to an embodiment of the present invention. Forming 320 a stub comprises applying 322 a nanoparticle to the substrate surface; and creating 324 an isolation layer on and in the substrate surface using the nanoparticle to mask an underlying location of the substrate surface where the isolation layer is not created and the stub will be formed. Using the nanoparticle in this self-aligned process both creates 324 a built-in isolation layer and forms 320 the stub; and as provided below, facilitates growth 340 of the nanowire from the stub.

In some embodiments, the substrate surface is a non-single crystal semiconductor seed layer on a non-single crystal substrate material. The seed layer is deposited on the substrate surface using PECVD, for example. FIG. 4A illustrates a side view of a substrate 410 and a microcrystalline semiconductor substrate surface 412 having nanoparticles 150 applied to the substrate surface 412 according to this embodiment. In other embodiments, the substrate surface is the surface of a single crystal semiconductor substrate material. FIG. 5A illustrates a side view of a single crystal semiconductor substrate 510 with nanoparticles 150 applied to a substrate surface 512 of the single crystal semiconductor substrate 510 according to this embodiment.

Nanoparticles may be applied 322 in a variety of ways to the substrate surface. For example, nanoparticles may be dispersed in a liquid solvent that is applied 322 to the substrate surface, such as by a spin coating technique. The liquid solvent is evaporated such that the nanoparticles remain on the substrate surface in random locations. In another example, nanoparticles are deposited 322 on the substrate surface in a thin film, such as by using a spray coating technique, and then the thin film is annealed to create discontinuities between the nanoparticles. In these examples, the nanoparticles are in a solid, powder form and their application 322 provides a disordered distribution of nanoparticles on the substrate surface. For example, the nanoparticles may be a colloidal suspension of gold (Au) particles in a toluene solvent. In another example, the nanoparticles may be applied 322 using electrochemical deposition. Electrochemical deposition may offer selectivity in terms of locations on a surface where the nanoparticle deposition takes place.

The isolation layer may be created 324 using a technique that consumes the substrate surface during creating 324. In some embodiments, the isolation layer comprises one of an oxide and a nitride of the semiconductor surface. In other embodiments, the isolation layer may be a carbide of the semiconductor surface or another dielectric material formed from the semiconductor surface material. In some embodiments, creating 324 an isolation layer comprises using thermal oxidation. In other embodiments, creating 324 an isolation layer comprises using a plasma-assisted technique, such as plasma oxidation or plasma anodization. A plasma-assisted technique, such as plasma oxidation, is a relatively low temperature process compared to thermal oxidation. For example, thermal oxidation of a surface to provide a quality isolation layer (e.g., relatively pin-hole free) may use temperatures above 400° C. to achieve. In contrast, plasma oxidation and plasma anodization of a surface to provide an equivalent quality isolation layer uses temperatures below 400° C. For example, temperatures at or below about 200° C. are possible, including a temperature range of 100° C.-150° C., for example. The relatively lower temperature plasma-assisted process for creating 324 an isolation layer has numerous advantageous. Not only may the lower temperature process increase a number of available materials useful for fabricating the photovoltaic structure, but also, the lower temperature process may decrease cost. In other embodiments, the isolation layer may be created 324 using atomic layer deposition (ALD) that uses metal organic precursors. ALD may provide one or both of good conformality and selectivity (i.e., an ALD-film will not deposit on a metallic surface but will deposit on a semiconductor surface).

During creating 324 an isolation layer, a portion of the substrate surface is consumed to create both a portion of the isolation layer that is embedded in the substrate surface and a portion of the isolation layer overlying embedded portion or ‘on the substrate surface’. For example, an isolation layer created 324 in and on a silicon substrate surface using either a thermal oxidation process or a plasma oxidation process will comprise a silicon oxide isolation layer that is electrically isolating. In some embodiments, a thickness of the isolation layer ranges from about 5 nanometers (nm) to about 50 nm, for example. The embedded portion of the isolation layer has a thickness that may range from about 2 nm to about 20 nm, for example. The surface portion of the isolation layer has a thickness that may range from about 3 nm to about 30 nm, for example. By ‘about’ it is meant that the values provided herein encompass normal material and process variations, for example.

The nanoparticle is not consumed during the creation 324 of the isolation layer. Moreover, the nanoparticle mask protects a location of the substrate surface under the nanoparticle from consumption during creating 324 an isolation layer. The protected location is the self aligned, formed 320 stub. During creating 324 an isolation layer, the embedded portion of the isolation layer undercuts the nanoparticle mask at a periphery of the nanoparticle mask. In some embodiments, a width of the nanoparticles ranges from about 5 nm to about 50 nm, for example. The embedded portion of the isolation layer may undercut the nanoparticle periphery by an amount not to exceed 5 nm, for example. As such, the underlying stub is narrower than the nanoparticle used to mask it. Said another way, a width of the formed 320 stub is smaller than the width of the nanoparticle. Further, a stub formed 320 according to this embodiment has a height that is as tall as the thickness of the embedded portion of the isolation layer. The surface portion of the isolation layer is stopped at the periphery of the nanoparticle. Sidewalls of the formed 320 stub may be relatively vertical or may be tapered as a result of creating 324 the isolation layer, depending on embodiment. A tapered stub sidewall is wider at a base of the stub than at the upper surface of the stub adjacent to the nanoparticle.

FIG. 4B illustrates a side view of the created isolation layer 130 according to some embodiments of the present invention. FIG. 4C illustrates a magnified view of one of the stubs from FIG. 4B according to this embodiment. As illustrated, an embedded portion 132 of the isolation layer 130 undercuts a periphery of the nanoparticle 150, while a surface portion 134 of the isolation layer 130 abuts the nanoparticle 150. FIG. 4C illustrates that the sidewalls of the formed 320 stub are relatively vertical with respect to a horizontal plane of the substrate in some embodiments, by way of example. FIGS. 4B and 4C further illustrate that an area underlying the nanoparticle 150 (i.e., the self-aligned, formed 320 stub) remains unchanged from being the microcrystalline material and continuous with the microcrystalline surface layer 412.

In some embodiments, forming 320 a stub further comprises etching the substrate surface using the nanoparticle as an etch mask before creating 324 an isolation layer. In this embodiment, the nanoparticle protects or masks an underlying location of the substrate surface during etching. A dry etching technique, for example reactive ion etching (RIE), or wet etching may be used to etch the substrate surface. After etching, a pre-stub made of the substrate surface material is formed that has relatively taller sidewalls than the embodiment illustrated in FIG. 4C. FIG. 5B illustrates a cross sectional view of the single crystal substrate 510, the surface 512 of which is etched to form pre-stubs 120a, according to an embodiment of the present invention. Also after etching, the nanoparticle remains on the upper surface of the pre-stub 120a while the isolation layer is created 324. Although not illustrated, it should be noted that the microcrystalline substrate surface illustrated in FIG. 4A may further include etching to form 320 a taller microcrystalline stub, in some embodiments. The description herein of etching the single crystal substrate embodiment, illustrated in FIG. 5A and 5B, is provided by way of example only.

FIG. 5C illustrates a side view of creating 324 an isolation layer 130 that also transforms the pre-stubs 120a to the stubs 120 according to an embodiment of the present invention. In this embodiment, during creating 324 an isolation layer, the isolation layer 130 further consumes some of the sidewalls of the pre-stubs (120a). A relatively vertical extending embedded portion 132 is created in the sidewall of the pre-stubs (120a) when the isolation layer 130 undercuts at the periphery of the nanoparticle 150, similar to the undercutting described above. Moreover, a surface portion 134 of the isolation layer 130 forms on the sidewall of the stubs adjacent to the relatively vertical embedded portion 132. The relatively vertical surface portion 134 of the isolation layer 130 may or may not exceed the height of the stubs 120 plus the nanoparticle 150. As such, in this embodiment, a self-aligned, stub is formed 320 that is taller than the built-in, created 324 isolation layer is thick in a horizontal plane, but still narrower than the nanoparticle 150. Moreover, the self-aligned stub is surrounded by the relatively vertical portions 132, 134 of the built-in isolation layer 130 on the sidewalls of the stub. The thickness of the isolation layer on the sidewalls of the stubs may be different from the thickness of the isolation layer on the substrate surface (in the horizontal plane). The difference in thickness between the horizontally extending isolation layer and the relatively vertical extending portion of the isolation layer depends on the fabrication process conditions.

FIG. 5C further illustrates that the area underlying the nanoparticle 150 (i.e., the self-aligned, formed 320 stub) remains unchanged from the single crystal semiconductor substrate material and remains continuous with the substrate surface 512. The stub 120 and the pre-stub 120a are illustrated in FIGS. 5B-5E with vertical sidewalls by way of example only. It should be understood that these stubs 120, 120a may have a tapered shape, in some embodiments, where the stub is wider at a base of the stub than at the upper surface thereof. As such, the term ‘relatively vertical’ is used only for the purpose of describing the upright portions of the isolation layer on the sidewalls of the formed stub and it is not intended as a limitation herein.

Referring back to FIG. 3A, as mentioned above, the method 300 of fabricating a photovoltaic structure further comprises growing 340 a nanowire from the upper surface of the stub. According to the various embodiments herein, the nanoparticle further catalyzes nanowire growth 340 in a self-aligned process from the stub. FIGS. 4D and 5D illustrate nanowire growth 340 from upper surfaces of respective formed 320 stubs according to various embodiments of the present invention. Note that in the various embodiments, a base of the self-aligned nanowire 140 is larger than the stub 120 and overlies at least the embedded portion 132 of the isolation layer 130 adjacent to the stub 120. Further illustrated in FIG. 4D, an axial length segment of the nanowire 140 that is adjacent to the nanowire base also overlies a part of the surface portion 134 of the isolation layer 130 in the vicinity of the stub in this embodiment. FIG. 5D illustrates the base of the nanowire 140 overlying both relatively vertical portions 132, 134 of the isolation layer 130 in the vicinity of the stub in this embodiment.

The nanoparticle 150 remains on a free end of the nanowire 140 which is opposite to the base end of the nanowire that is integrally connected to the stub 120. Although not illustrated in FIG. 4D, the self-aligned nanowires 140 grow in relatively chaotic directions from the respective self-aligned stubs 120 because the stubs 120 are a microcrystalline material with relatively non-uniform crystallites at the upper stub surface, as described above with respect to at least the solar cell 200 embodiment of the photovoltaic cell 100. Therefore, the angles and the growth directions of the nanowires are disordered. FIG. 4D illustrates a relatively uniform direction of the nanowires for simplicity of illustration only. For an illustration of the disordered nanowire growth from microcrystalline stubs, according to some embodiments, see for example, the illustration in FIG. 2.

In contrast, referring to the embodiment illustrated in FIGS. 5A-5D, the self-aligned nanowires 140 grow in a relatively uniform direction from the self-aligned, single crystal stubs, also as described above. FIG. 5D illustrates a relative perpendicular uniform growth according to this embodiment. The uniform perpendicular direction of the nanowires 140 illustrated in FIG. 5D is shown by way of example. The nanowires may grow in a relatively uniform direction at other angles to a horizontal plane of the substrate instead of perpendicular; the direction of growth depends on the crystal direction of the single crystal material of the substrate surface.

Growing 340 a nanowire comprises using a catalytic growth process, for example a vapor-liquid-solid (VLS) epitaxial growth using the nanoparticle as a catalyst. In some embodiments, a combination of catalytic growth and non-catalytic growth are used to manipulate a shape of the nanowire along its axial length. In some embodiments, nanowire growth is initiated in a CVD reaction chamber using a gas mixture of a nanowire source material that is introduced into the chamber at a growth temperature and using the nanoparticle catalyst. For example, indium phosphide (InP) nanowires may be grown using metal organic CVD (MOCVD). In this example, trimethylindium and phosphine in a hydrogen carrier gas may be used with a gold-silicon alloy material as the metal nanoparticle catalyst on a silicon-based stub. The InP nanowires are anchored to the stub and have metallic tips comprising gold in this example.

In some embodiments, the method 300 of fabricating further comprises conformally coating 360 the nanowires with a layer of an electrically conductive material. By ‘conformally coating’, it is meant that the material coats the nanowires by following contours of the nanowire along the axial length of the nanowire. In effect, the nanowire surfaces are passivated by the conformal coating. In some embodiments, the conformal layer further covers the contours of the isolation layer on the substrate surface between and around the nanowires. The conformal layer may be conformally coated 360 on the contours of the nanowire using plasma enhanced chemical vapor deposition (PECVD), for example. In some embodiments, the previously described non-single crystal materials and the previously described single crystal materials may be conformally coated 360 on the nanowire with PECVD. In some embodiments, the conformal layer is coated 360 on the nanowires to a thickness ranging from about 5 nm to about 100 nm.

In some embodiments, conformally coating 360 the nanowires comprises growing a single crystal, semiconductor layer on the nanowires in the same CVD chamber used for nanowire growth 340. In some of these embodiments, the conformal layer will cover only the nanowires. For example, a thin layer of highly doped indium gallium arsenide (InGaAs) may be conformally grown 360 on indium phosphide (InP) nanowires. In other embodiments, a multilayer conformal coating may be grown on the nanowires in the same CVD chamber used for nanowire growth 340. Such a multilayer conformal coating provides for creating a concentric semiconductor junction along the axial length of the nanowire, for example.

In an example, an extrinsic semiconductor nanowire is first grown in the CVD chamber. One or both of parameters and precursor materials are then changed and a first sublayer of the conformal layer is grown as a single crystal intrinsic semiconductor on the nanowire surface. Subsequent to the growth of the first sublayer, one or both of parameters and precursor materials are changed again and a second or outer sublayer is grown as an extrinsic semiconductor on the first sublayer. As such, a concentric p-i-n semiconductor junction is formed during conformally coating 360 the nanowire. Moreover, the second sublayer of the conformal layer may be a single crystal semiconductor or a non-single crystal semiconductor, depending on the embodiment. If the second sublayer is single crystal, the second or outer sublayer will remain under the nanoparticle at the free end of the nanowire. Alternatively, if the second sublayer is non-single crystal, the second or outer sublayer will cover the nanoparticle at the free end of the nanowire due to a change in growth process, but in the same CVD chamber. The photovoltaic structure 105 illustrated in FIG. 1D exemplifies one embodiment of the concentric semiconductor junction formed during conformally coating 360 the nanowire.

A benefit to growing the conformal coating on the nanowires in the same reaction chamber is that the nanowire surfaces are passivated prior to exposure to ambient conditions. Since the extrinsic semiconductor conformal layer coats only the nanowires in this example, an electrical connection between spaced apart, conformally coated nanowires may be subsequently created with a top electrical contact formed over the conformally coated structure, as described further below.

The dopant type of the semiconductor conformal layer is opposite to or the reverse of the dopant type of the extrinsic semiconductor stub (i.e., ‘opposite’ or ‘reverse’ dopant type means a p-type dopant vs. an n-type dopant). In some embodiments, the semiconductor conformal layer comprises an intrinsic region (e.g., first sublayer) and an extrinsic region (e.g., second sublayer), wherein the dopant type of the extrinsic region is the reverse of the extrinsic semiconductor stub. In some embodiments, the conformal layer is equivalent to the conformal layer 160 described above for any of the photovoltaic cell 100 embodiments and the solar cell 200 embodiments.

In some embodiments (not illustrated in FIG. 3A), the method 300 of fabricating a photovoltaic structure further comprises forming an external electrical connection to opposite ends of the nanowire. In these embodiments, an electrical contact is deposited on the substrate to access a base end of the nanowire that is connected to the stub. In some embodiments, the base or bottom electrical contact is applied to the substrate prior to forming 320 a stub. For example, sputter coating or e-beam evaporation may be used to deposit the bottom electrical contact. In some of these embodiments, the base electrical contact is applied prior to depositing the microcrystalline layer of the substrate surface. For example, a non-electrically conductive amorphous substrate may be sputter coated with a layer of aluminum; then the microcrystalline semiconductor material is deposited over the aluminum layer using PECVD to form the substrate surface. In this example, the base electrical contact may coat the entire amorphous substrate, i.e., the sides, top and bottom of the substrate.

FIGS. 1D and 2 illustrate examples of a base electrical contact 180 provided on an amorphous substrate 110 to access the base end of the nanowire 140 according to some of these embodiments. Not illustrated in FIGS. 1D and 2 is that the base electrical contact 180 is accessible external to the respective photovoltaic cell 100, 200. In the embodiments illustrated in FIGS. 1D and 2, the base contact 180 is formed prior to or in conjunction with forming the microcrystalline layer 112 on the substrate 110. In some of these embodiments, the bottom electrical contact 180 coats the amorphous substrate on at least sides that are adjacent to the microcrystalline surface layer.

With respect to the embodiments illustrated in FIG. 1A and FIGS. 5A-5E, a base electrical contact 180 is applied after an electrical connection is formed to the free end of the nanowires 140, which is described further below. For example, the base electrical contact 180 may be sputter-coated on a side of the single crystal semiconductor substrate of these embodiments that is opposite to or adjacent to the substrate surface that comprises the stubs.

In some embodiments, a top electrical contact is deposited on the conformal layer to electrically access a free end of the nanowires that is opposite to the base end. In other embodiments, the conformal layer itself provides the electrical access to the free end of the nanowires and is the top electrical contact. For example, sputter coating or e-beam evaporation may be used to deposit the top electrical contact. The electrical contacts are equivalent to the electrical contacts 170, 180 described above for the photovoltaic cell 100 and the solar cell 200 embodiments. FIG. 5E illustrates a side view of a photovoltaic cell fabricated in accordance with FIGS. 5A-5D of the method 300 of the present invention. Both a top electrical contact 170 and a bottom electrical contact 180 are illustrated in the FIG. 5E by way of example. The fabricated photovoltaic cell in FIG. 5E comprises a top electrical contact 170 that is much thicker than the conformal layer 160 underneath. The top electrical contact 170 is a material that is both electrically conductive and optically transparent. The top electrical contact 170 may be applied using a sputter deposition technique, for example.

Thus, there have been described embodiments of a photovoltaic structure of a photovoltaic cell, a solar cell and a method of fabricating a photovoltaic structure that employ a self-aligned nanowire on a self-aligned stub surrounded by a built-in isolation layer. It should be understood that the above-described embodiments are merely illustrative of some of the many specific embodiments that represent the principles of the present invention. Clearly, those skilled in the art can readily devise numerous other arrangements without departing from the scope of the present invention as defined by the following claims.

What is claimed is:

1. A photovoltaic structure of a photovoltaic cell comprising:
a stub that is a constituent of a substrate surface;
a nanowire having a base connected to the stub, the nanowire extending away from the substrate surface, the nanowire being wider than the stub;
an electrical isolation layer surrounding the stub, the nanowire base overlying a part of the electrical isolation layer that is adjacent to the stub; and
a semiconductor junction that comprises the nanowire.

2. The photovoltaic structure of claim 1, further comprising an electrically conductive coating that conformally covers the nanowire, wherein the isolation layer electrically isolates the electrically conductive coating from the stub.

3. The photovoltaic structure of claim 2, wherein the stub and the substrate surface comprise a first extrinsic semiconductor, the nanowire comprising an intrinsic semiconductor, the electrically conductive coating comprising a second extrinsic semiconductor, the semiconductor junction being a p-i-n junction between the electrically conductive conformal coating, the nanowire and the stub.

4. The photovoltaic structure of claim 1, wherein the isolation layer comprises a portion embedded in the substrate surface and a portion on the substrate surface overlying the embedded portion, the stub being at least as tall as a thickness of the embedded portion of the isolation layer, the nanowire base overlying the embedded portion of the isolation layer surrounding the stub.

5. The photovoltaic structure of claim 1, wherein the stub is taller than the isolation layer is thick measured from a horizontal plane of the substrate, part of the isolation layer extending along sidewalls of the stub, the nanowire base overlying the part of the isolation layer that extends along the sidewalls of the stub.

6. The photovoltaic structure of claim 1, wherein the substrate surface is a seed layer of a non-single crystal extrinsic semiconductor on a non-single crystal substrate, the stub being a constituent of the seed layer extrinsic semiconductor.

7. A solar cell comprising:
a plurality of stubs comprising an extrinsic semiconductor, the stubs being constituents of a surface of a substrate;
a plurality of nanowires connected to the stubs and extending away from the substrate surface, the nanowires comprising one or both of an intrinsic semiconductor and an extrinsic semiconductor;
an electrical isolation layer surrounding the stubs, the stubs being narrower than the nanowires such that a base of the nanowires connected to the stubs overlies a part of the isolation layer adjacent to the stubs;
a conformal layer that coats the nanowires, the conformal layer being electrically conductive;
a semiconductor junction that comprises the nanowires; and
an electrical connection that separately electrically accesses opposite ends of the nanowires.

8. The solar cell of claim 7, wherein the electrical isolation layer is an oxide of the substrate surface, a portion of the oxide being embedded in the substrate surface and a portion being on the substrate surface, the stub being at least as tall as a thickness of the embedded portion of the oxide measured in a horizontal plane of the substrate, the conformal layer further covering the electrical isolation layer between the nanowires.

9. The solar cell of claim 7, wherein the conformal layer comprises a first sublayer of an intrinsic semiconductor integrally attached to the nanowires and a second sublayer of an extrinsic semiconductor attached to the first sublayer, the nanowires comprising an opposite dopant type from the extrinsic semiconductor of the second sublayer, the semiconductor junction comprising a p-i-n junction between the nanowires, the first sublayer and the second sublayer, and
wherein the electrical connection comprises an electrical contact that electrically interconnects the conformally coated nanowires to access an end of the nanowires that is opposite to the nanowire base and an electrical contact on the substrate to access the nanowire base.

10. The solar cell of claim 7, wherein the substrate is a non-single crystal substrate, the substrate surface comprising a microcrystalline surface layer of the extrinsic semiconductor of the stubs, the stubs being constituents of the microcrystalline surface layer, and
wherein the plurality of stubs is randomly located on the substrate surface, the nanowires extending from the stubs at a variety of angles to the substrate surface in a disordered array, the plurality of nanowires reducing light reflection.

11. A method of fabricating a photovoltaic structure, the method comprising:
forming a stub in a substrate surface, wherein forming a stub comprises:
applying a nanoparticle to an extrinsic semiconductor surface of a substrate; and
creating an electrical isolation layer on and embedded in the semiconductor surface, the nanoparticle masking an underlying portion of the semiconductor surface from the isolation layer, the underlying portion being the stub, the stub being narrower than the nanoparticle;
growing a nanowire from the stub using the nanoparticle to catalyze nanowire growth, wherein a portion of the nanowire overlies a part of the isolation layer that is adjacent to and surrounding the stub; and
conformally coating the nanowire with an electrically conductive conformal layer.

12. The method of fabricating of claim 11, wherein creating an electrical isolation layer comprises growing an oxide of the semiconductor surface, wherein the stub has a width that is less than a width of the nanoparticle.

13. The method of fabricating of claim 11, wherein forming a stub further comprises etching the substrate surface using the nanoparticle as an etch mask to form a pre-stub before creating an electrical isolation layer, the stub being taller than a thickness of the created isolation layer measured from a horizontal plane of the substrate, the created isolation layer further being on and embedded into sidewalls of the stub such that the stub is narrower than the nanoparticle.

14. The method of fabricating of claim 11, wherein conformally coating the nanowire comprises one or both of forming a semiconductor junction with the nanowire and providing electrical access to the nanowire from an end of the nanowire that is opposite to the stub, wherein the isolation layer electrically isolates the conformal layer from the stub.

15. The method of fabricating of claim 11, further comprising providing the semiconductor surface before providing a nanoparticle, wherein providing the semiconductor surface comprises depositing a non-single crystal semiconductor seed layer on the substrate, the semiconductor seed layer providing crystallites that facilitate growing a nanowire from the stub, the substrate being a non-single crystal material.
